(19) United States
(12) Patent Application Publication
(10) Pub. No.: US 2015/0288129 A1
(43) Pub. Date: Oct. 8, 2015

(54) Optically Surface-Pumped Edge-Emitting Devices and Systems and Methods of Making Same

(71) Applicant: VERLASE TECHNOLOGIES LLC, Shelburne, VT (US)

(72) Inventor: Ajaykumar R. Jain, San Carlos, CA (US)

(73) Assignee: VERLASE TECHNOLOGIES LLC, Winooski, VT (US)

(21) Appl. No.: 14/441,199

(22) PCT Filed: Nov. 4, 2013
(86) PCT No.: PCT/US2013/068257

§ 371 Date: May 7, 2015

Related U.S. Application Data
(60) Provisional application No. 61/797,000, filed on Nov. 28, 2012.
(60) Provisional application No. 61/849,056, filed on Jan. 18, 2013.

(51) Int. Cl. H01S 3/067; H01S 3/094; H01L 33/10; H01S 5/04; H01L 33/00; H01S 3/0941; H01S 5/183

(52) U.S. Cl. CPC H01S 3/06708; H01S 3/0941; H01S 3/06754; H01S 3/094084; H01S 5/183; H01S 3/0675; H01S 5/041; H01L 33/0045; H01L 33/105

(57) ABSTRACT

Optical resonator devices and systems enhanced with photoluminescent phosphors and designed and configured to output working light in an edge-emitting fashion at one or more wavelengths based on input/pump light, and systems and devices made with such resonators. The edge-emitting functionality is enabled by providing one or more waveguides that direct light luminesced from the phosphors to one or more edges of the device. In some embodiments, the resonators contain multiple optical resonator cavities in combination with one or more photoluminescent phosphor layers or other structures. In other embodiments, the resonators are designed to simultaneously resonate at the input/pump and output wavelengths. The photoluminescent phosphors can be any suitable photoluminescent material, including semiconductor and other materials in quantum-confining structures, such as quantum wells and quantum dots, among others.

### RELATED APPLICATION DATA

This application claims the benefit of priority of U.S. Provision Patent Application Ser. No. 61/797,000, filed on Nov. 28, 2012, and titled “NOVEL METHODS TO INCREASE THE EFFICIENCY OF OPTO-ELECTRONIC DEVICES.” This application also claims the benefit of priority of U.S. Provisional Patent Application Ser. No. 61/849,056, filed on Jan. 18, 2013, and titled “NOVEL METHODS TO INCREASE THE EFFICIENCY OF OPTO-ELECTRONIC DEVICES.” Each of these applications is incorporated herein by reference in its entirety.

### FIELD OF THE INVENTION

The present invention generally relates to the field of optoelectronic devices. In particular, the present invention is directed to optically surface-pumped edge-emitting devices and systems and methods of making same.

### BACKGROUND

Researchers and engineers are continually striving to improve the performance, efficiency, quality, etc., of optoelectronic devices such as light-emitting diodes (LEDs), laser diodes (LDs), and other light-emitting devices, as well as to create lower cost light-emitting devices, and devices emitting in portions of the electromagnetic spectrum that currently lack high-quality, low-cost solutions, such as in the case of the so-called “green gap” that exists for green-light-emitting semiconductor-based LEDs and LDs.

Photoluminescent materials have been used as optical gain media for various light-emitting devices. However, the quantity of such materials used in many of these devices and the increased complexity of some of these devices make them more expensive than desired. In addition, conventional usage of photoluminescent materials has not solved problems that continue to exist, such as the green gap noted above.

### SUMMARY OF THE DISCLOSURE

In one implementation, the present disclosure is directed to an optical system. The optical system includes an optical device designed and configured to output working light of a first spectral composition in response to receiving pumping light of a second spectral composition different from the first spectral composition, the optical device including a plurality of layers having a stacking direction, first and second faces spaced along the stacking direction, and an edge extending between the first and second faces, wherein the plurality of layers are designed, arranged, and configured to define a resonator cavity designed and configured to resonate at a resonant frequency tuned to the second spectral composition; a first photoluminescent layer located within the resonator cavity, the first photoluminescent layer designed and configured to create luminescence of the first spectral composition in response to stimulation by the pumping light when the pumping light is received through at least one of the first and second faces; and a waveguide designed and configured as a function of the first spectral composition so as to guide the luminescence toward the edge so as to output the working light through the edge.

In another implementation, the present disclosure is directed to a method of making an optical system that includes an optical device designed and configured to output working light from an edge of the optical device in response to being pumped with pumping light through a face of the optical device. The method includes arranging and configuring a plurality of layers within the optical device so as to define at least one resonator cavity designed and configured to resonate at a spectral frequency of the pumping light; providing a first photoluminescent layer within the at least one resonator cavity, wherein the first photoluminescent layer is designed and configured to provide luminescence in response to the pumping light; and providing a waveguide to guide the luminescence toward the edge of the optical device so as to output the working light through the edge of the optical device.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a diagrammatic representation of an optical system made in accordance with the present invention and that includes an optically surface-pumped edge-emitting (OSPEE) resonator;

FIGS. 2A to 2E are diagrammatic representations of OSPEE resonators, illustrating exemplary waveguide locations;

FIG. 3A is a diagrammatic representation of an optical system that includes a multi-layer OSPEE resonator;

FIG. 3B is an edge view of the multi-layer OSPEE resonator of FIG. 3A;

FIG. 4A is a diagrammatic view of a multi-layer OSPEE resonator having absentee layers, each located between the phosphor layer and a corresponding resonator reflector; and

FIG. 4B is a diagrammatic view of a multi-layer OSPEE resonator having absentee layers each located within a corresponding resonator reflector.

FIG. 5 is an isometric view of an OSPEE, illustrating various light-pumping schemes and work light outputs;

FIG. 6 is an edge view of an OSPEE resonator having a phosphor layer of varying thickness;

FIG. 7 is an edge view of an OSPEE resonator having a plurality of phosphor layers of differing thicknesses;

FIG. 8 is a diagrammatic view of an optical system having an OSPEE resonator and having a multi-pass configurations for pumping light;

FIG. 9 is a diagrammatic view of an OSPEE resonator that includes a waveguide having a cylindrical shape; and

FIG. 10 is a diagrammatic view of an OSPEE resonator that also has a cylindrical waveguide, wherein the resonator-reflector layers are conformal with the waveguide.

### DETAILED DESCRIPTION

Some aspects of the present invention are directed to optical devices that each include at least one optically surface-pumped edge-emitting (OSPEE) resonator designed and configured to output working light via at least one edge of the resonator in response to receiving pumping light through at least one face, or surface, of the resonator. Each OSPEE resonator contains one or more photoluminescent materials and includes one or more optical resonator cavities, as well as one or more optical waveguides for guiding the luminescent light emitted from the photoluminescent material(s) and directing it to one or more edges of the OSPEE resonator to create the working light. As those skilled in the art will readily appreciate, the pumping light will have a spectral composition that is different from the spectral composition of the output working light by virtue of the stimulative and emissive, i.e., luminescent, properties of the photoluminescent material(s). Each OSPEE resonator contains one or more resonator cavities tuned to resonate at one or more frequencies within the spectral composition of the output working light, the pumping light, or both. By properly selecting the spectral composition of the pumping light and the photoluminescent material(s), and by carefully tuning the resonant frequency(ies) of the resonator cavity(ies) and carefully designing the optical waveguide(s), a designer can finely tune the spectral composition of the edge-emitted output working light to suit a particular application. Indeed, with proper design and execution, optical systems made in accordance with the present invention can readily achieve output working light of a quality and spectral composition heretofore not easily achieved using conventional technologies.

Other aspects of the present invention include, but are not limited to: 1) applying pumping light to an OSPEE resonator at one or more non-normal angles of incidence; 2) customizing OSPEE resonators for optimal laser-diode(LD)-like performance, super-luminescent-light-emitting-diode (SLED)-like functionality, and semiconductor-optical-amplifier-like performance; 3) using fixed or varying amounts of photoluminescent material(s) within a single layer and/or multiple layers to generate output light of varying spectral composition; 4) optimizing OSPEE resonators to implement a multi-pass resonator or a waveguided, circular cross-section phosphor; 5) pumping both faces of an OSPEE resonator and/or outputting light through more than one edge of the resonator; 6) tuning OSPEE resonators relative to the modal output, including single mode, multi-mode, transverse electric (TE) transverse magnetic (TM) modes/orientations; and 7) optimizing OSPEE resonators for specific polarization. These and other aspects of the present invention are described below in connection with several exemplary embodiments. Those skilled in the art, however, will readily appreciate that the disclosed embodiments are merely exemplary and that many other embodiments can be derived and instantiated using the broad teachings of this disclosure. Before proceeding to describe exemplary embodiments, several terms used through this disclosure and in the appended claims are first defined immediately below.

A “spectral composition” of light includes a single wavelength, multiple wavelengths, and/or a band of wavelengths of visible or invisible electromagnetic radiation.

A “stacking direction” defines the direction of layering within an optical device; such layering can be planar or nonplanar (e.g., curved or having discontinuities) layering and can be layering for any component(s) of the device, such as photoluminescent layers and sub-layers, reflector layer(s) (e.g., distributed Bragg reflector (DBR) layers and non-DBR reflector layers), absentee layers, waveguide layers, light-source layers, among others. It is noted that a “non-DBR reflector,” or non-distributed Bragg reflector” covers any reflector that does not have layers of thicknesses conventionally associated with DBRs but are nonetheless reflectors suitable for the applications identified herein.

A “face” of an optical device is defined by a surface of a layer that is perpendicular to the stacking direction of a plurality of layers that form at least a portion of an optical device. A “face” can be internal to a layered structure, such as in a case where a light source is formed monolithically with an edge-emitting device. In this case, a “face” can be a boundary such as, for example, an outermost layer of a DBR or non-DBR reflector layer.

An “edge” of an optical device is defined by a plane extending between opposing faces. An edge can extend the entire distance or just a portion of the distance between the faces and can extend perpendicularly from the faces or form any other desirable angle with the faces. An edge of an optical device containing a cylindrical, hexagonal, or other closed-shape waveguide contains an end of the waveguide and is positioned along the longitudinal axis of the waveguide.

A “photoluminescent layer” is a layer within an optical resonator that includes at least some photoluminescent material, i.e., one or more phosphors, that is selected in conjunction with pumping light to luminesce in response to the pumping light. A photoluminescent layer can be composed of a single layer or a plurality of sub-layers, depending upon a particular design.

“Working light” is light that is emitted from at least one edge of an optical resonator and used for some purpose. In the context of the present invention, “working light” results from the luminescence of photoluminescent material within a photoluminescent layer of the optical device that is in response to illuminating the photoluminescent material with pumping light.

A “waveguide” is an optical waveguide intentionally created to direct luminescence from the photoluminescent material to at least one edge of an optical device in order to create the working light. In the context of an OSPEE-resonator-based system of the present disclosure, a waveguide can be provided, for example, by various layers that form the resonator cavity(ies), by one or more separate confinement heterostructure stacks incorporated into the resonator layer stack, or by a waveguiding structure, such as a sheath, sleeve, layer stack, etc., located externally to the resonator cavity(ies), among others. It is noted that each waveguide can be located symmetrically or asymmetrically relative to the midpoint axis of a corresponding resonator cavity.

A “midpoint axis” of a resonator cavity is an axis located at the functional midpoint of the cavity.

An “absentee layer” or “absentee optical layer” is a layer that has a thickness that is an even multiple of one-quarter of the wavelength of the light for which the relevant optical structure, such as a waveguide, is being designed.

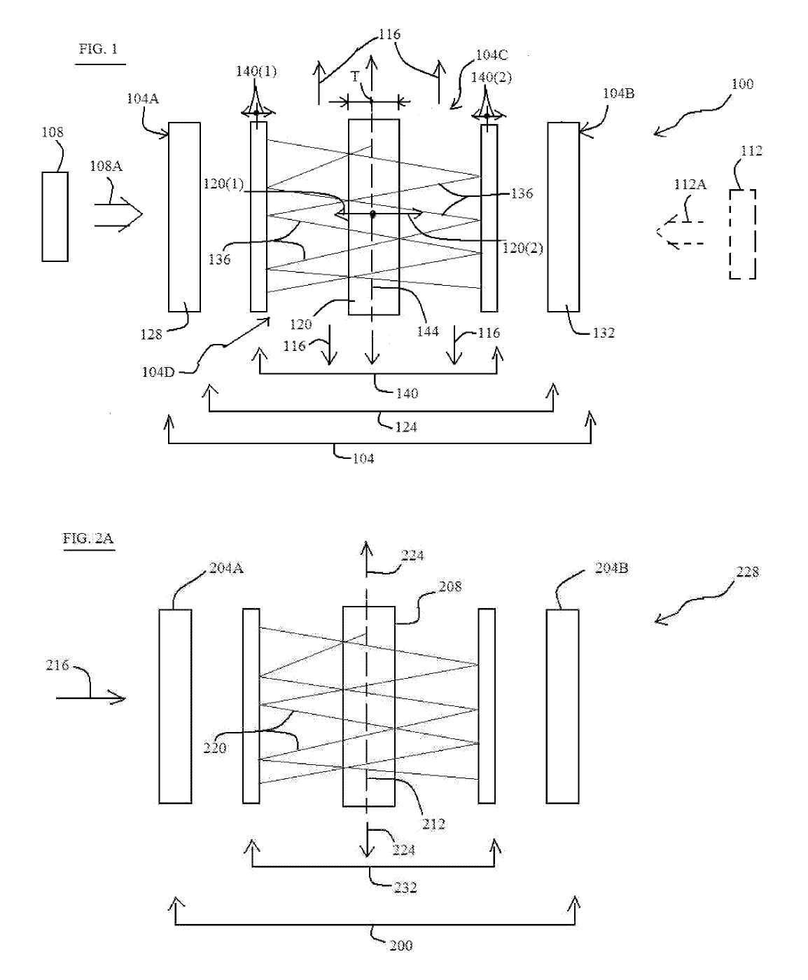

Turning now to the drawings, FIG. 1 illustrates primary elements and an exemplary general configuration of an optical system 100 made in accordance with the present invention. Optical system 100 comprises an OSPEE resonator 104 and one or more pumping-light sources, here two sources 108 and 112, designed, configured, and located to pump the OSPEE resonator with corresponding respective pumping light 108A and 112A via one or more of the faces, here faces 104A and 104B of the resonator. It is noted that in alternative embodiments, an optical system similar to optical system 100 may include fewer or more than two pumping-light source 108 and 112. Each pumping-light source, such as pumping-light sources 108 and 112, used may be any light source that emits light with the necessary spectral composition, such as an LED, SLED or LD, among others, or any combination thereof. Fundamentally, the only requirements for a light source suitable for a pumping-light source of the present disclosure, such as either of pumping-light sources 108 and 112 of FIG. 1, are spectral composition of the output light relative to the photoluminescent material(s) used, intensity of the output light, and compatibility of size with the OSPEE resonator. Each pumping-light source 108 and 112 can be formed integrally with OSPEE resonator 104 or can be formed separately and subsequently placed into the proper operating relationship with the OSPEE resonator. Those skilled in the art will readily understand, after reading this entire disclosure, how to provide one or more light sources to an optical system of the present disclosure by monolithic integration with the OSPEE resonator or otherwise, such that detailed explanations of such is not required herein for skilled artisans to make and use the present invention to its fullest scope as represented by the appended claims.

OSPEE resonator 104 is designed and configured to output working light 116 via one or more edges, here edges 104C and 104D of the OSPEE resonator, in response to pumping light 108A and 112A and as a function of one or more photoluminescent layers (only one layer 120 shown for simplicity) located within the resonator. In the manner noted above, the spectral composition of working light 116 will typically be different from the spectral composition(s) of pumping light 108A and 112A by virtue of the luminescing characteristics of the photoluminescent material(s) within photoluminescent layer(s) 120. As will be readily appreciated, the spectral composition of pumping light 108A and 112A includes light of the frequency composition needed to stimulate luminescence within the photoluminescent material(s) present in photoluminescent layer(s) 120. It is noted that while photoluminescent layer 120 is shown having a uniform thickness, T, this does not necessarily mean that all photoluminescent layers provided in accordance with the present invention need have uniform thicknesses, nor does it necessarily mean that the photoluminescent material(s) present within each of such layers needs to be uniformly distributed. On the contrary, any photoluminescent layer can have a non-uniform thickness, for example, a linearly or non-linearly changing thickness, and/or can have a non-uniform distribution of photoluminescent material(s) within it.

OSPEE resonator 104 includes one or more resonator cavities (only one cavity 124 shown for convenience) each designed and configured to contain one or more of photoluminescent layer(s) 120. It is noted that each photoluminescent layer within a particular resonator cavity, such as photoluminescent layer 120 within resonator cavity 124, can be adjusted in locations within that cavity, as indicated by arrows 120(1) and 120(2). Each resonator cavity 124 is also designed and configured to resonate at the stimulative frequency(ies) of the photoluminescent material(s) within the corresponding respective one(s) of the photoluminescent layer(s) in order to increase the intensity of the stimulation of such photoluminescent material(s) and thus, increase the intensity of the light emitted by the photoluminescent material(s) so as to make working light 116 more intense. Each resonator cavity 124 is defined by suitable first and second reflectors 128 and 132 that are precisely designed and configured to optically resonate at one or more stimulative frequencies of the photoluminescent material(s) 120 within the photoluminescent layer(s) 120 of that particular resonator cavity. In one example, each of first and second reflectors 128 and 132 is a DBR, which those skilled in the art will understand how to form.

Lines 136 (only a few labeled to avoid clutter) illustrate the generally isotropic nature of the luminesced light 136 emitted from the photoluminescent material(s) within any of photoluminescent layers 120 during periods of excitation by an appropriate application of pumping light, here pumping light 108A and 112A. In order to control the directionality of the output working light 116 that is emitted from one or more of the edges, such as edges 104C and 104D of edge-emitting optical resonator 104, the optical resonator includes one or more waveguides (only one waveguide 140 shown for convenience) for directing portions of isotropic luminesced light 136 to the desired edge(s). Each waveguide 140 is tuned to the specific spectral composition of the relevant luminesced light 136. As noted above, such tuning can include tuning relative to the modal output, including single mode, multi-mode, TE and TM modes/orientations, as well as tuning/optimizing for specific polarization. Arrows 140(1) and 140(2) indicate that each waveguide 140 is adjustable in location relative to a midpoint axis(es) 144 of the corresponding resonator cavity(ies) 124.

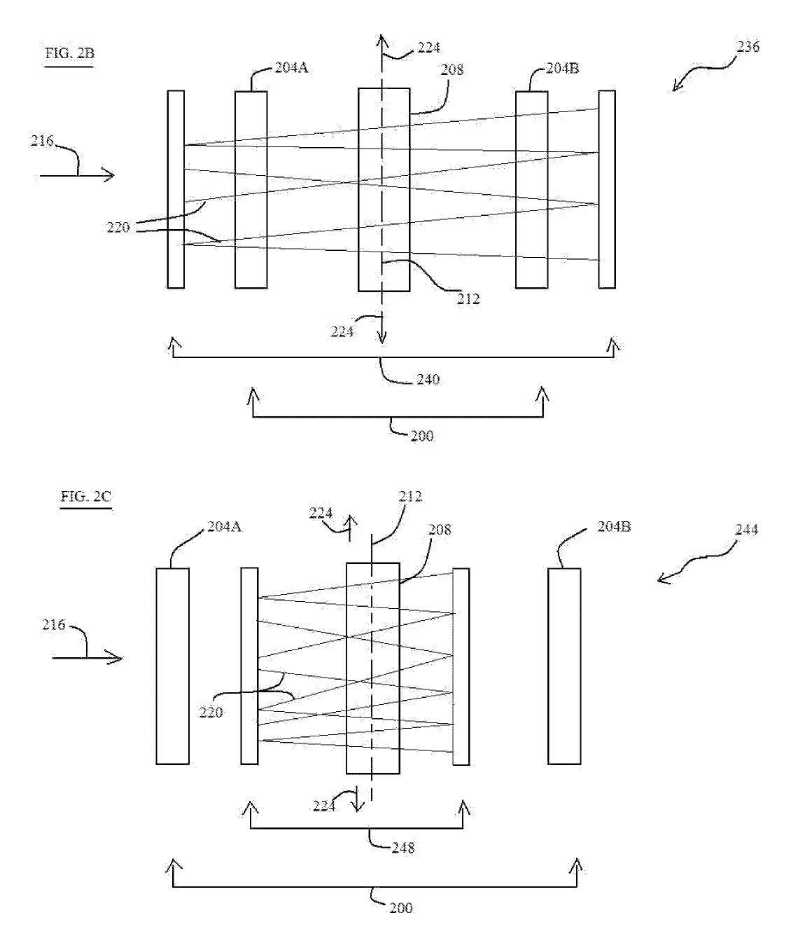

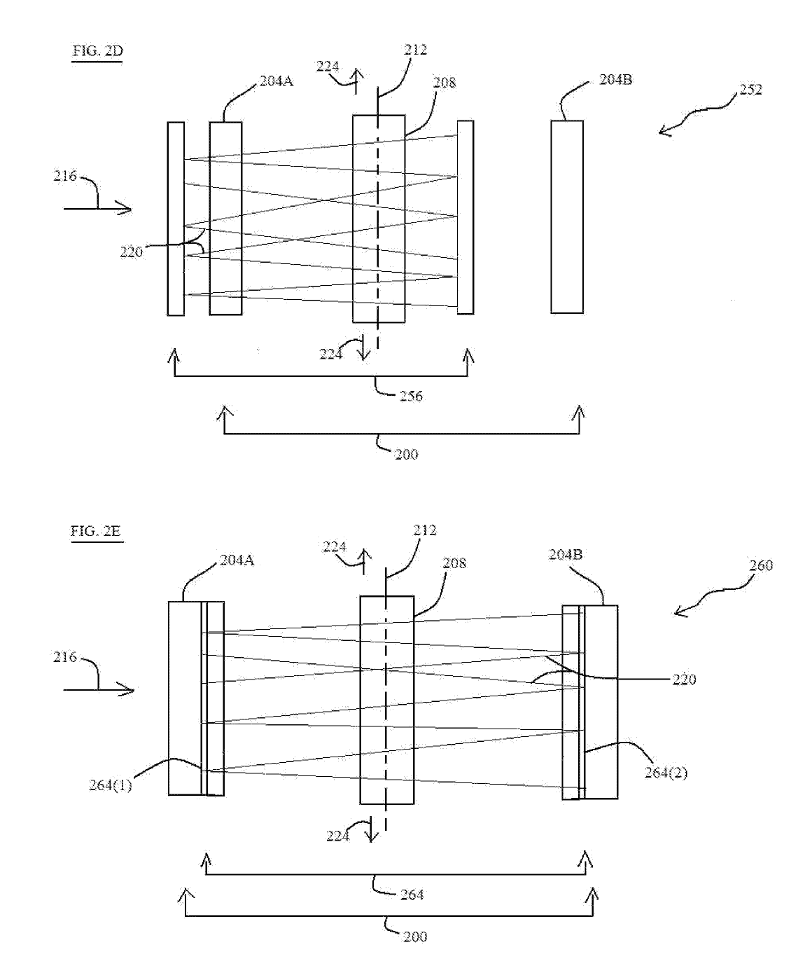

A waveguide of an OSPEE resonator of the present disclosure, such as waveguide 140 of OSPEE resonator 104 of FIG. 1, 1) can be located concentrically within respect to the midpoint axis of a corresponding resonator cavity, such as relative to midpoint axis 144 of resonator cavity 124 so as to be either between first and second reflectors 128 and 132 or contain these reflectors, 2) can be located eccentrically respect to such midpoint axis, for example, between first and second reflectors 128 and 132, straddling one or the other of these reflectors, or as to contain both reflectors, or 3) can be located completely outside of the corresponding resonator cavity. In this connection, it is noted that a waveguide, such as waveguide 140, can be located nearly anywhere relative to the corresponding resonator cavity, i.e., inside, outside, straddling the inside and outside, etc., because the spectral composition of the phosphor-emitted light, for example, emitted light 136, is different from the spectral composition of the pumping, or excitation, light, such as pumping light 108A and 112A. Therefore, the optical-resonator reflectors, such as first and second reflectors 128 and 132, which are tuned to the spectral composition of the pumping light, do not interfere with the transmission of the emitted light to regions within the optical resonator reflectors and outside and even to regions outside the optical resonator reflectors altogether. Consequently, a waveguide can be located virtually anywhere relative to the resonator cavity(ies). FIGS. 2A to 2E illustrate examples of waveguide locations in several single-resonator-cavity OSPEE systems made in accordance with the present invention.

Referring now to FIGS. 2A to 2E and noting that in each of these figures the resonator cavity is denoted by element numeral “200”, the resonator cavity reflectors are denoted by element numerals “204A” and 204B”, the photoluminescent layer is denoted by element numeral “208”, the midpoint axis of the resonator cavity is denoted by element numeral “212,” the pumping light is represented by arrows “216”, the luminesced light is represented by lines “220” (only a few labeled to avoid clutter), and the working light is represented by arrows “224”. Regarding the representations of the various types of light, those skilled in the art will readily appreciate that these representations are merely generalizations. With these things in mind: FIG. 2A illustrates an OSPEE device 228 in which the waveguide 232 is located concentrically with midpoint axis 212 and entirely within resonator cavity 200; FIG. 2B illustrates an OSPEE device 236 in which the waveguide 240 is located concentrically with midpoint axis 212 and contains resonator cavity 200; FIG. 2C illustrates an OSPEE device 244 in which the waveguide 248 is located eccentrically relative to midpoint axis 212 and is contained entirely within resonator cavity 200; FIG. 2D illustrates an OSPEE device 252 in which the waveguide 256 is located eccentrically relative to midpoint axis 212, is located partly within and partly outside resonator cavity 200, and contains photoluminescent layer 208; and FIG. 2E illustrates an OSPEE device 260 in which the waveguide 264 is located so that the waveguide reflectors 264(1) and 264(2) are located, respectively, within resonator cavity reflectors 204A and 204B.

Those skilled in the art will readily appreciate that the examples of FIGS. 2A to 2E are merely illustrative, and that many other variations can be made to achieve a desired OSPEE resonator design, including variations in number of waveguides, variations in number of photoluminescent layers, variations in shape of the photoluminescent layer(s), variations in location(s) of the photoluminescent layer(s), variations in the number of resonator cavities, variations in the locations of input light, variations in number and location of the edges from which working light is emitted, and any suitable combination thereof.

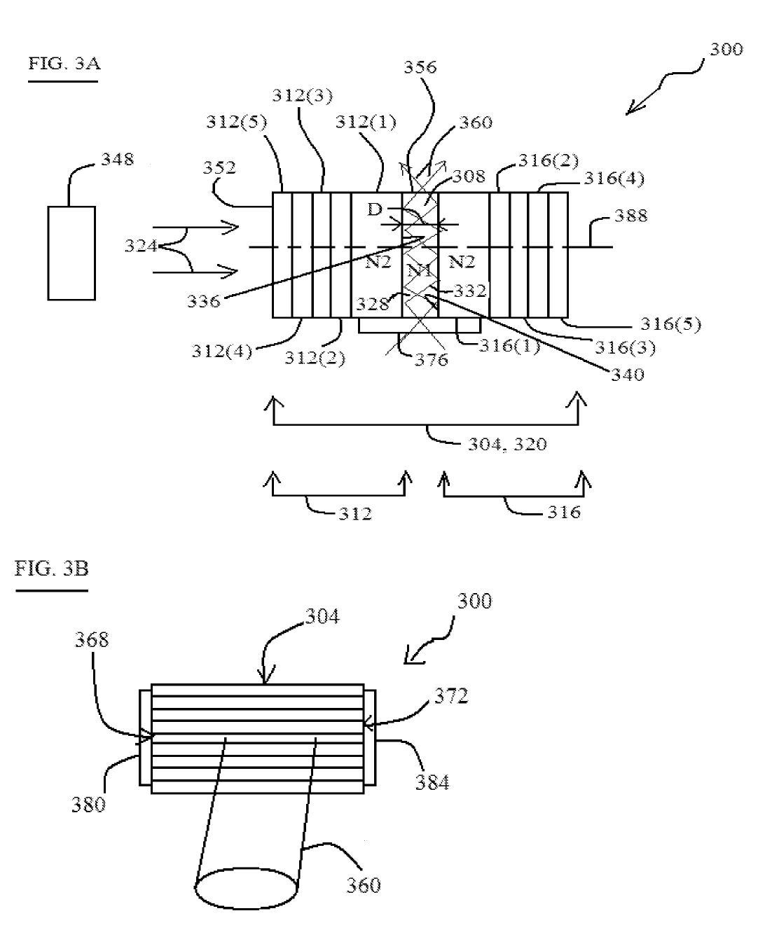

As those skilled in the art will readily understand, a suitable waveguide, for example waveguide 140, for the emitted light can be formed within an OSPEE resonator, such as OSPEE resonator 104 of FIG. 1, by bounding a waveguiding region having a first refractive index with regions having second refractive indices lower than the first refractive index of the waveguiding region, wherein the bounding lower-index regions are spaced from one another by a distance that is a function of the spectral composition of the emitted light to be guided. This is illustrated in FIGS. 3A and 3B, which show an optical system 300 that includes a multilayer OSPEE resonator 304 made in accordance with the present invention. In exemplary optical system 300, OSPEE resonator 304 includes a photoluminescent layer 308 that has a refractive index N1 and is sandwiched between two DBR stacks 312 and 316 in which layers 312(1) and 316(1) of the corresponding respective stack, i.e., the layer of each stack located immediately adjacent to the photoluminescent layer, has a refractive index of N2. DBR stacks 312 and 316 are provided to define a resonator cavity 320 that receives the pumping light 324.

As those skilled in the art will understand, when N2<N1, photoluminescent layer 308 becomes a waveguide 328 for luminesced light 332 emitted from the photoluminescent material within the photoluminescent layer due to total internal reflection (TIR) at the reflective boundaries 336 and 340 created by the reductions in refractive indices N1 and N2 across the interfaces of layers 312(1) and 316(1) with the photoluminescent layer 308. Similar to the description above relative to FIG. 1, luminesced light 332 results from pumping light 324, which in this example is provided by a pumping light source 348 via face 352 of OSPEE resonator 304. Waveguide 328 directs a significant portion of luminesced light 332 to edge 356 of OSPEE resonator 304 to providing working light 360. In this example, other edges of OSPEE resonator 304, i.e., edge 364 (FIG. 3A) and edges 368 and 372 (FIG. 3B) can optionally include corresponding respective feedback mirrors 376, 380, and 384 that intensify working light 360 output via edge 356. As those skilled in the art will readily appreciate, the distance, D, between reflective boundaries 336 and 340 can be selected to control characteristics of working light 360. While layers 312(1) and 316(1) in the embodiment shown are provided with a refractive index N2 lower than refractive index N1, those skilled in the art will readily appreciate that the refractive indices of all layers 312(1) to 312(5) and 316(1) to 316(5) can be selected so that any pair of these layers, for example, one in each of DBR stacks 312 and 316, can be the layers that provide the reflective boundaries for waveguide 328. The thicknesses of all of the layers of OSPEE resonator 304 can also be judiciously selected to ensure proper functioning of the OSPEE resonator relative to tuning of resonator cavity 320 and waveguide 328. Other aspects and features of optical system 300 not particularly described can be the same as or similar to like aspects and features of optical system 100 of FIG. 1.

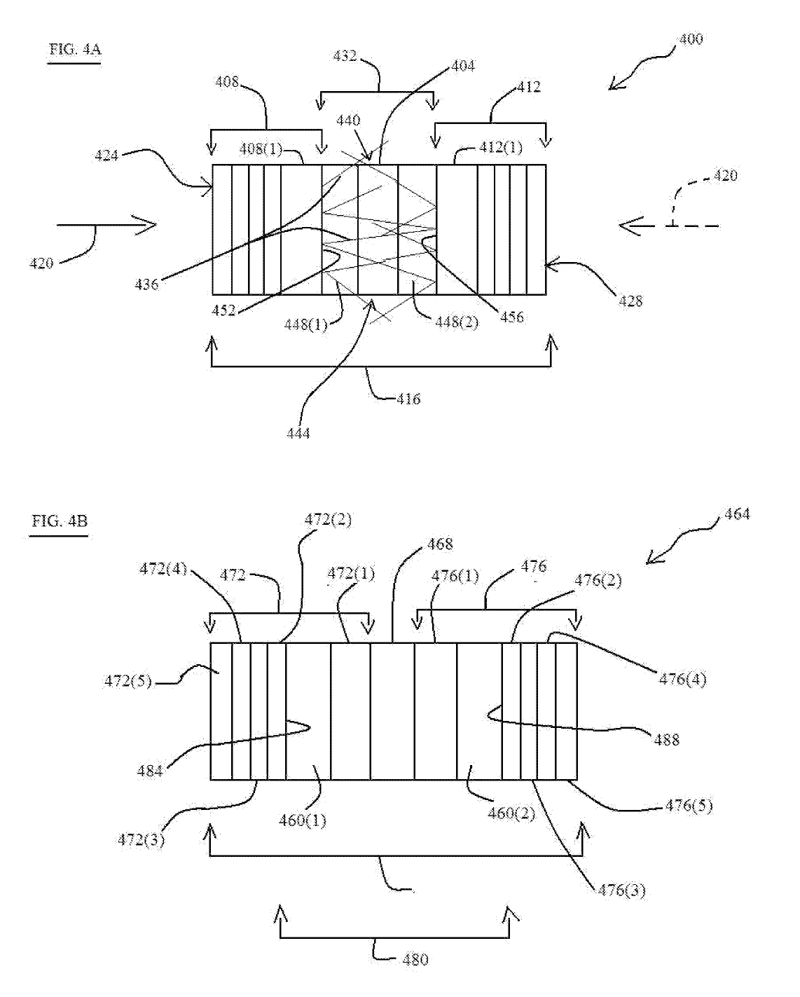

The locations of the reflective boundaries of the waveguide relative to the corresponding resonator cavity(ies) and photoluminescent layer(s) may depend on a particular application and/or is for a designer to decide. In addition, as those skilled in the art will understand, one or more absentee optical layers can be used where needed to accommodate useful waveguide designs. The usage of various absentee layers is illustrated in FIGS. 4A and 4B. Referring first to FIG. 4A, this figure shown an OSPEE resonator 400 made in accordance with the present invention. OSPEE resonator 400 includes a photoluminescent layer 404 and a pair of DBR reflector stacks 408 and 412 that define a resonator cavity 416 that receives pumping light 420 input into the resonator via face 424 or face 428 or both of these faces. OSPEE resonator 400 also includes a waveguide 432 for guiding luminesced light 436 from photoluminescent layer 404 toward one or more of the edges of the OSPEE resonator, such as edges 440 and 444. In this example, waveguide 432 is partially formed using a pair of absentee layers 448(1) and 448(2) located correspondingly respectively between DBR reflector stack 408 and photoluminescent layer 404 and DBR reflector stack 412 and the photoluminescent layer. In this example, layers 408(1) and 412(1) of DBR reflector stacks 408 and 412 are provided with a refractive indices that are lower than the refractive indices of absentee layers 448(1) and 448(2) and photoluminescent layer 404 so as to create the reflective boundaries 452 and 456 of waveguide 432.

Referring now to FIG. 4B, this figure illustrates the fact that the one or more absentee layers, here absentee layers 460(1) and 460(2), can be located elsewhere in an OSPEE resonator of the present disclosure, here OSPEE resonator 464. As seen in FIG. 4B, OSPEE resonator 464 includes a photoluminescent layer 468 and a pair of DBR reflector stacks 472 and 476 that are located immediately adjacent to the photoluminescent layer. Instead of absentee layers 460(1) and 460(2) being located between DBR reflector stacks 472 and 476 and photoluminescent layer 468 as they are in OSPEE resonator 400 of FIG. 4A, they are located among the various layers 472(1) to 472(5) and 476(1) to 476(5) of the reflector stacks. This provides a waveguide 480 that has a width, W, between reflective boundaries 484 and 488 that are defined by layers 472(2) and 476(2) having refractive indices that are lower than the refractive indices of absentee layers 460(1) and 460(2), layers 472(1) and 476(1), and photoluminescent layer 468. In other embodiments, the one or more absentee layers can be located elsewhere within the reflector stacks or even outside the reflector stacks as desired to suit a particular design. As with all layers described herein, each absentee layer provided can be singular or made of more than one sublayer as design thicknesses and formation techniques may dictate. Those skilled in the art will readily appreciate how to design, configure, and locate a waveguide suitable for the present invention according to known optical waveguide design principles such that further explanation is not necessary for those skilled in the art to design, make, and use edge-emitting optical resonators of the present invention.

As evident from examples presented above, an OSPEE resonator of the present disclosure, such as any of the OSPEE resonators described above relative to FIGS. 1 to 4B, may be made of multiple layers of suitable materials having the requisite properties. Examples of properties of ones of the various layers, such as each photoluminescent layer, layers for defining resonator cavity reflectors, such as DBR layers, absentee layers, and layers for forming each waveguide, among others, that may need to be considered for design purposes include, but are not limited to, translucence to the requisite wavelength(s), refractive indices, thicknesses, and composition. The layers may be deposited, grown, or otherwise formed using known processing techniques, such as techniques commonly used in the semiconductor and optical fabrication industry.

When an OSPEE resonator of the present invention, such as OSPEE resonator 304 of FIGS. 3A and 3B, is composed of multiple layers, the layers may be considered to be “stacked” along a stacking axis that is generally perpendicular to each layer in the optical resonator at the location of the axis. For example, if each layer is planar as depicted in FIGS. 3A and 3B, then the resulting stacking axis 388 is normal to, for example, a face plane of each layer and also face 352. In alternative embodiments, however, edge-emitting optical resonators of the present invention can be curved such that each layer has a face that is non-planar, such as curved in one or more direction. In such cases, the resulting stacking axis can be defined relative to the non-planar faces of the various layers as being locally substantially perpendicular to each of those faces.

FIG. 5 depicts an OSPEE resonator device 500 comprising a photoluminescent layer 504, a pair of resonator reflector layers 508 and 512 (each of which may comprise a suitable DBR stack) that define a resonator cavity 516 for pumping light 520, and a waveguide 524 for guiding luminesced light 528 to one or more of the edges 532(1) to 532(4) of the resonator device to create the working light 536. In this example, OSPEE resonator device 500 is created by a faceting process to expose edges 532(1) to 532(4). FIG. 5 illustrates that pumping light 520 can be input to OSPEE resonator device 500 via one, the other, or both of faces 540(1) and 540(2) (here, just face 540(1)) and at any suitable pair of angles θ and Φ relative to a pair of axes parallel to face 540(1). Essentially the only limitation on angles θ and Φ is that they do not result in an undesirable amount of internal and/or external reflection that would interfere with pumping light reaching photoluminescent layer 504. As noted above relative to OSPEE resonator 304 of FIGS. 3A and 3B, each of one or more of edges 532(1) to 532(4) can be provided with a feedback minor (not shown) to inhibit luminesced light 528 from exiting that edge and for intensifying working light 536 output through the non-mirrored one(s) of edges 532(1) to 532 (4). Those skilled in the art will readily understand how to form such feedback mirror(s). It is noted that while four edges 532(1) to 532(4) are shown, an OSPEE resonator of the present disclosure can have any number of edges, which can be formed by known techniques, such as faceting and cutting, etc. Other aspects and features of OSPEE resonator 500 not particularly described can be the same as or similar to like aspects and features of other OSPEE resonators described herein.

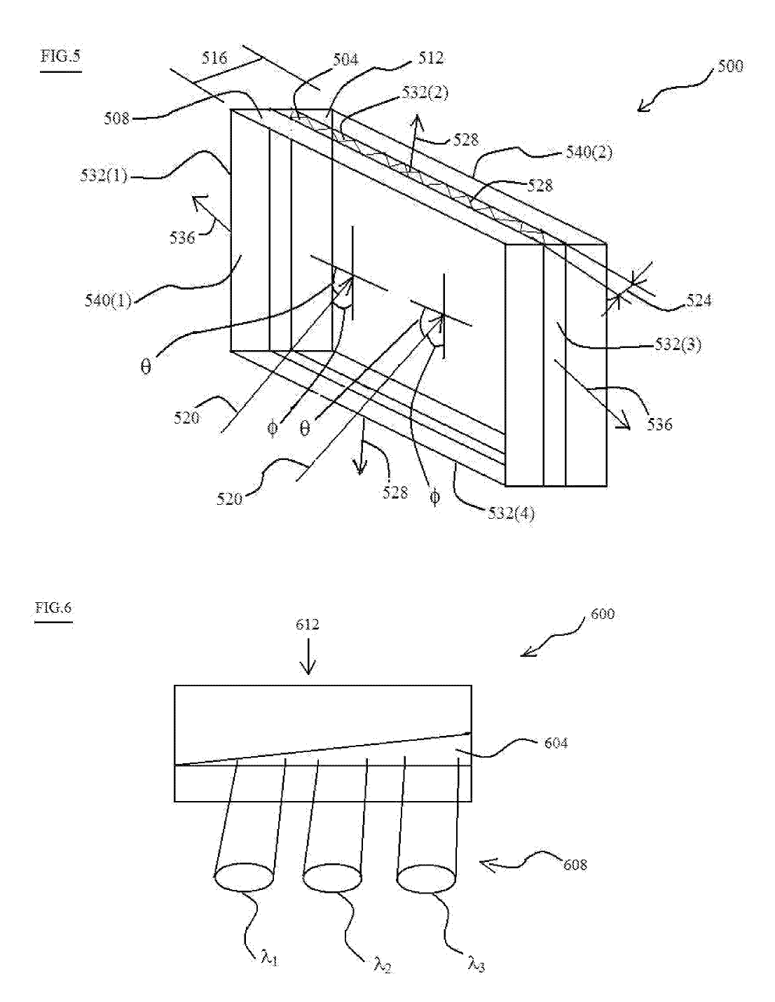

The foregoing illustrated examples depict OSPEE resonators that each contain a single, uniformly thick photoluminescent layer. However, in other embodiments and as noted above, more than one photoluminescent layer may be used, and each, some, or all of the one or more of the photoluminescent layers in each optical resonator can have a non-uniform thickness. Such an implementation can be designed with waveguiding layers that are also either uniformly-thick, correspondingly non-uniformly thick, or both. Depending on the thickness(es) of the photoluminescent layers, OSPEE resonators can be designed to take advantage of quantum-confining effects within the photoluminescent layer(s) so as to tune the frequency(ies) of the luminesced light output from these layer(s). An example of this is illustrated in FIG. 6, which shows an OSPEE resonator 600 containing a photoluminescent layer 604 having a non-uniform thickness, here, a thickness having a constant rate of change, resulting in the photoluminescent layer having a wedge shape. In thickness regimes wherein quantum-confinement effects are evident, the regions of differing thickness within photoluminescent layer 604 can result in the working light 608 having different wavelengths, here λ₁, λ₂, and λ₃, and/or amplitudes corresponding to the differing regions in the presence of uniform pumping light 612. It is noted that the thickness of photoluminescent layer 604 need not have a monotonic slope as depicted in FIG. 6. Indeed, other geometries are possible, such as stepped geometries and geometries having various curvatures and/or discontinuities. In such a configuration, the wavelengths of the luminesced light and working light 608 may be substantially contained within a single plane. In FIG. 6, working light 608 is depicted as coming out of the page generally at the viewer. This is due to the presence of a waveguide (not shown) within OSPEE 600. Though specific sub-regions of photoluminescent layer 604 in FIG. 6 are shown emitting light for illustration purposes, those skilled in the art will readily appreciate that the photoluminescent layer may emit light from specific sub-regions or along its entire length depending on the area(s) of the photoluminescent layer that is/are optically-pumped.

Various techniques exist for creating non-uniform-thickness photoluminescent layers, such as photoluminescent 604. For example, a photoluminescent layer of substantially uniform thickness may be preferentially etched/ablated to create the layer thickness variation desired. Direct etching may be done by ion beam etching, chemical etching, laser assisted etching, photo-ablation, directed plasma etching, etc. Techniques such as gray scale lithography and micro/nano imprinting may be used to create the desired patterns in a photoresist; the pattern can then be subsequently transferred into a photoluminescent layer using isotropic or anisotropic etching mechanisms to create the layer thickness variation desired.

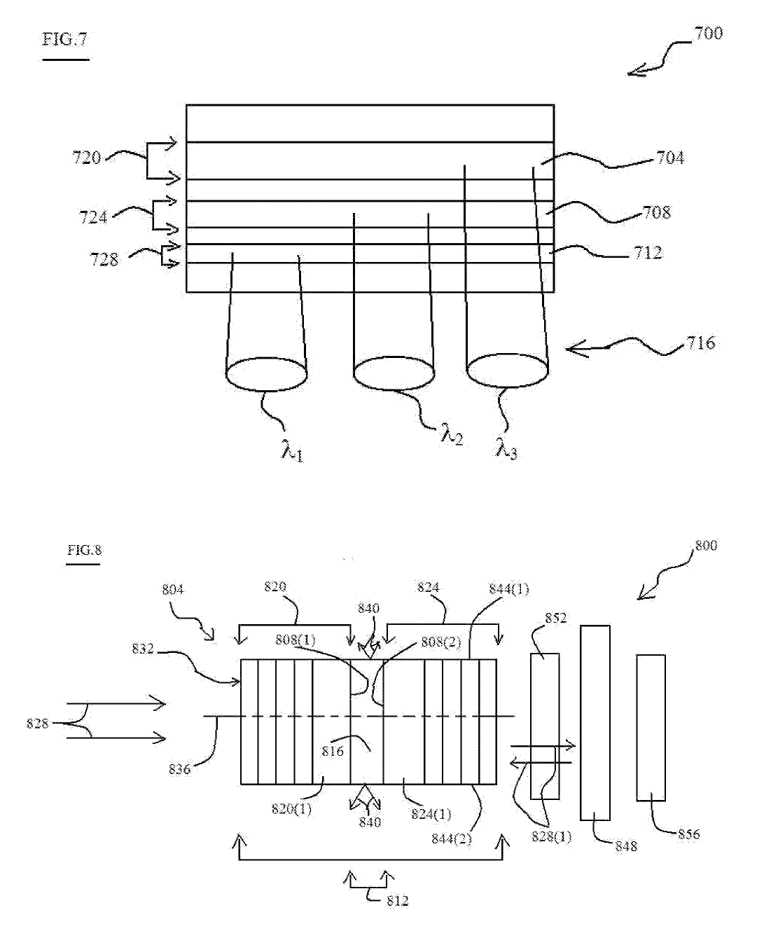

In some situations, it may be advantageous to provide multiple photoluminescent layers of differing thicknesses. For example, FIG. 7 illustrates an OSPEE resonator 700 having three photoluminescent layers 704, 708, and 712 of differing thickness. In some embodiments, the light luminesced from individual ones of photoluminescent layers 704, 708, and 712 can differ in wavelength from layer to layer (e.g., due to differing chemistries and/or differing quantum-confinement parameters), such that the working light 716 emitted from OSPEE resonator 700 is composed of differing wavelengths, here, λ3, λ2, and λ1, respectively. In such a configuration, each of the output light wavelengths λ1, λ2, and λ3 may be substantially contained within differing planes. As with FIG. 6, though specific sub-regions of photoluminescent layers 704, 708, and 712 are shown emitting light in FIG. 7 for illustration purposes, the photoluminescent layer may emit output light from specific sub-regions or along its entire length depending on the area(s) of each photoluminescent layer that is/are optically-pumped. In the embodiment shown, each photoluminescent layer 704, 708, and 712 has its own waveguide 720, 724, and 728 that does not permit mixing of the luminesced light from one of the photoluminescent layers to another, keeping spectral separation. In other embodiments, photoluminescent layers 704, 708, and 712 may all be located within a common waveguide, such that there is spectral mixing of the differing wavelengths λ1, λ2, and λ3 in the luminesced light and, therefore, working light 716, too.

Each photoluminescent layer of an OSPEE resonator made in accordance with the present disclosure can be composed of a single phosphor material or can be composed of multiple phosphor materials. For example, multiple activator species materials could be embedded in the same host or multiple hosts and then inserted into an optical resonator cavity. Quantum dots of varying sizes and compositions could be mixed together or stacked on top of each other and then inserted into an optical resonator cavity. Similarly, quantum wells and other quantum-confining structures of varying sizes and compositions may be mixed together or stacked on top of each other and then inserted into an optical resonator cavity. Multi-layer semiconductor films of varying thicknesses and compositions may be mixed together or stacked on top of each other and then inserted into an optical resonator cavity.

An optical system made in accordance with the present invention can be configured to create a multi-pass system in which pumping light that is not absorbed by the photoluminescent layer(s) is directed back into the OSPEE resonator. An example of such a multi-pass optical system 800 is illustrated in FIG. 8. Referring now to FIG. 8, multi-pass optical system includes an OSPEE resonator 804, which can be, for example, any of the OSPEE resonators particularly illustrated or described herein. In the example shown, OSPEE resonator 804 is similar to OPSEE resonator 304 of FIGS. 3A and 3B in that the reflective boundaries 808(1) and 808(2) of the waveguide 812 are formed by a difference in refractive indices between the photoluminescent layer 816 and the immediately adjacent layers 820(1) and 824(1) of resonator reflector stacks 820 and 824, respectively. In the embodiment shown, pumping light 828 is initially input into OSPEE resonator 804 via face 832 in a direction along the stacking axis 836 of the various layers of the OSPEE resonator, and working light 840 is output via edges 844(1) and 844(2).

To provide multi-pass functionality, multi-pass optical system 800 includes a partial or full feedback mirror 848 that re-directs a portion 828(1) of pumping light 828, that does not get absorbed by photoluminescent layer 816 on its first pass through OSPEE resonator 804, back into the OSPEE resonator for an additional pass and opportunity to be absorbed by the photoluminescent layer. Feedback minor 848 can be located in physical contact with OSPEE resonator 804 or can be located at a desired distance away from the OSPEE resonator. In addition, mirror 848 may be positioned to be perpendicular to stacking axis 836 or to be at a non-90° angle relative to the stacking axis in either or both of a pair planes (not shown) that contain the stacking axis and are orthogonal to one another. A multi-pass configuration can allow for two or more passes, as desired. If needed, a transparent heat sink 852, which is transparent to pumping light 828, may optionally be provided between minor 848 and OSPEE resonator 804 to provide active cooling to the OSPEE resonator. Also optionally, alternatively or in addition to transparent heat sink 852, an opaque heat sink 856, which is opaque to pumping light 828, may be provided on the side of mirror 848 opposite OSPEE resonator 804. Both heat sinks 852 and 856 may be provided, if desired. It is noted that one or more multi-pass feedback minors similar to multi-pass feedback mirror 848 of FIG. 8 can be provided to any suitable optical system made in accordance with the present invention, such as the optical systems particularly described herein.

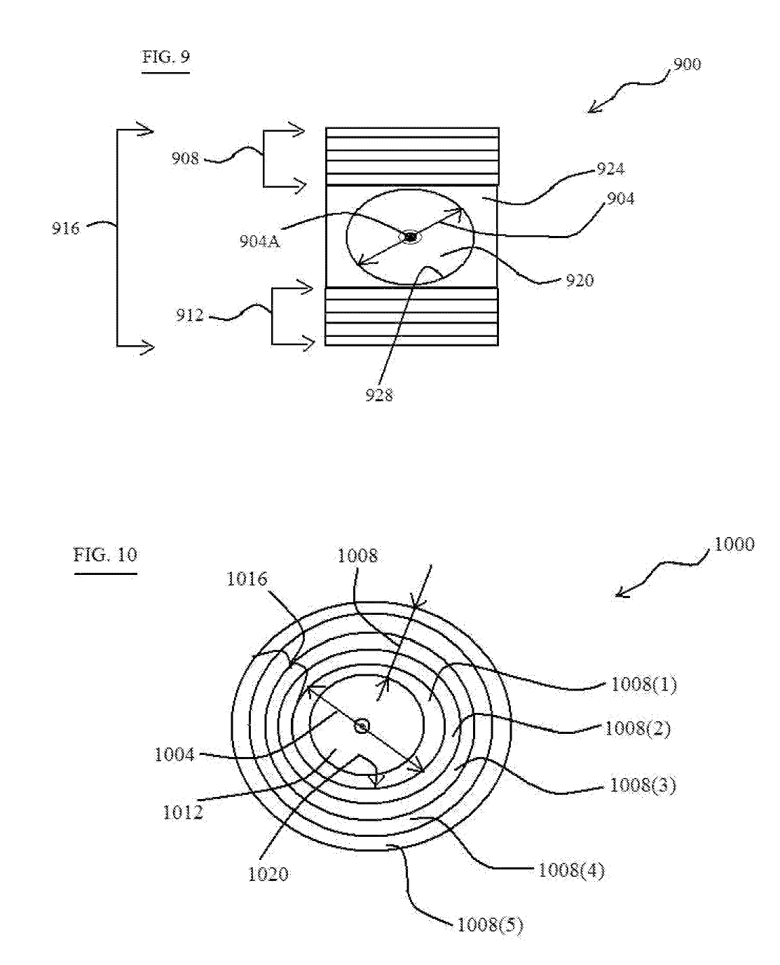

In the foregoing examples, the waveguides are formed by spaced planar reflectors. However, the present invention is not so limited, and OSPEE resonators of the present invention may include waveguides having other configurations, such as cylindrical. For example, FIG. 9 shows an OSPEE resonator 900 having a cylindrical waveguide 904 and a pair of planar resonator reflector stacks 908 and 912 forming a resonator cavity 916. In this embodiment, the longitudinal axis 904A of waveguide 904 runs into and out of the page of FIG. 9, and the waveguide may be considered to be filled with a phosphor region 920 that luminesces in response to pumping light (not shown) in the manner described above relative to other embodiments particularly disclosed herein. Waveguide 904 is formed by virtue of the fact that the refractive index of phosphor region 920 is higher than the region 924 immediately surrounding the phosphor region. Therefore, a reflective boundary 928 is formed between these two regions 920 and 924, and this reflective boundary provides the waveguiding functionality.

FIG. 10 another example of a OSPEE resonator 1000 of the present invention that includes a cylindrical waveguide 1004. In this example, a series 1008 of conformal layers is applied to a phosphor core 1012, with layers 1008(2) to 1008(5) effectively forming a cylindrical resonator DBR 1016 and layer 1008(1) providing an absentee layer. With this configuration, and with layer 1008(2) having a lower index of refraction than both absentee layer 1008(1) and phosphor core 1012 so as to define a reflective boundary 1020, waveguide 1004 is defined by reflective boundary 1020. It is noted that while the non-rectilinear waveguides shown are cylindrical, waveguides of other non-rectilinear shapes are also possible. However, it is not practicable to show or even list all such shapes, since they are numerous.

The foregoing description of important aspects and features of the present invention do not detail how one or more resonators may be designed and configured. However, the present inventor incorporates herein by reference, for its relevant teachings of same, PCT Patent Application PCT/US12/30540, filed on Mar. 26, 2012, and titled “RESONATOR-ENHANCED OPTOELECTRONIC DEVICES AND METHODS OF MAKING SAME.” For convenience, excerpts of that application are provided below. That said, it is important to note that other relevant information on how to design and configure resonators that can be used with OSPEE resonators of the present invention may be contained in material from that application not particularly repeated below. In such cases, the reader is encouraged to review that application.

Photoluminescent material can be composed of virtually any material that photoluminesces in the presence of input light and that produces the desired effect. Photoluminescent material can be located in any one or more of the optical resonator cavities of any one or more of the OSPEE resonators of the present disclosure in any of a variety of ways, depending upon the particular design at issue. For example, photoluminescent material in any one of cavities can be provided as a layer that defines or otherwise fills the entire cavity. In another example, photoluminescent material can be provided so as to partially fill a single cavity, such as being provided in a single layer having a uniform thickness less than the cavity length, a single layer having varying thickness within the cavity, and/or as multiple layers within the cavity that are separated by one or more other materials. In addition, it is noted that more than one type of photoluminescent material can be used within a single cavity and/or among multiple cavities, depending on the particular design at issue.

As will be seen from the exemplary embodiments described below, an OSPEE resonator according to the present invention can be implemented in a wide variety of ways to create new devices and systems and increase the efficiency of conventional devices and systems. As but one example, the OSPEE resonator can be designed as a downconverter to create a high-quality, high-brightness LED- or a LD type green light without the shortcomings of current generation green emitting LEDs and LDs. Judicious design using techniques described herein can also be used to create devices and systems at costs lower than the costs of corresponding conventional devices and systems. For example, while it is known to use various photoluminescent materials (which can be expensive) in conventional semiconductor-based light-emitting devices, those materials are typically provided in relatively thick layers (e.g., on the order of 100 s of micrometers) outside of the optical resonator cavity. However, as disclosed herein, much thinner phosphor layers (e.g., on the order of 10 s of nanometers or less) can be used if positioned inside one or more resonator cavities. These and other benefits of techniques and structures disclosed herein should become apparent from the exemplary embodiments described above.

Examples of photoluminescent materials that can be used in OSPEE resonators of the present invention include: macro-, micro-, and nano-powders (quantum powder) of rare earth dopant activators; bulk semiconductor materials (macro-, micro-, nano-powders); quantum-confining structures such as: quantum wells, quantum wires, quantum dots, quantum nanotubes (hollow cylinder), quantum nanowires (solid cylinder), quantum nanobelts (solid rectangular cross section), quantum nanoshells, quantum nanofiber, quantum nanorods, quantum nanoribbons, quantum nanosheets, etc.; and metallic nanodots, like gold nanodots, silver nanodots, aluminum nanodots, etc., among others. The photoluminescent material can be embedded in host materials like: crystals, glasses, glass-like compositions, sol gel, semi solid-gel, semiconductors, insulator materials like: oxides, nitrides, oxy nitrides, sulfides etc. Alternatively, organic host materials may also be chosen. It is understood that the host material may be amorphous, nano crystalline, micro crystalline, poly crystalline, textured or single crystal in morphology. Photoluminescent material may be made ex-situ and then bonded/deposited on top of the reflector coating of the optical cavity, alternatively, the photoluminescent material may be made/grown in-situ. As will be seen in examples below, photoluminescent material can be provided in any one or more of optical resonator cavities.

Many different semiconductor materials in thin-film form can be used as photoluminescent phosphor layers in devices and systems made in accordance with the present disclosure. These coating layers need not necessarily be quantum confining. These semiconductor thin films may be composed of any suitable material(s). These films can be single crystal, polycrystalline, preferentially oriented, textured, micro or nano crystalline or amorphous in morphology. Materials of particular interest for use in photoluminescent phosphor layers may be the wide band gap II-VI materials. Since II-VI semiconductors have direct energy gaps and large effective masses, they are very efficient in light absorption and emission. The II-VI materials may be composed of binary, ternary, or quaternary combinations such as: ZnS, ZnSe, ZnSSe, ZnTe, ZnSTe, ZnSeTe,CdS, CdSe, CdTe, CdSSe,CdSTe, CdSeTe, HgS, HgSe, HgTe, among others.

Each OSPEE resonator cavity may, for example, take the form of any of the following resonator architectures: plane parallel (also called “Fabry Perot”); concentric (spherical); confocal; hemispherical; concave-convex; Gires-Tournois interferometer, or any other suitable resonator architecture. Each optical resonator cavity can be defined by two reflectors, which may be any suitable type of reflector. The reflectors may be balanced (same reflectivity) or un-balanced (different reflectivity). Both reflectors may be integrated or one may be in intimate contact with a phosphor structure (integrated) while the other may not be in intimate contact with a phosphor structure within the OSPEE resonator. The OSPEE resonator may operate in the fundamental mode (smallest: λ/2 minor spacing, wherein λ is the particular design wavelength of resonance) or in any higher order mode (Non zero integer>1 multiple of λ/2 minor spacing). When optical resonator cavities are arranged in series, they may be coupled or non-coupled to each other. The coupling layer(s) (not shown) between resonator cavities can be of the first order (lambda/4 condition) or a higher order (odd integer>1 multiple of lambda/4) solution.

Other techniques for creating each OSPEE resonator can be used. Examples include utilizing photonic crystals, photonic cavities, sub-wavelength gratings, and other specialized structures for high reflectivity. Also, those skilled in the art will readily appreciate that each optical resonator may be created using microelectronic-mechanical systems, micro-optoelectronic-mechanical systems, nanoelectronic-mechanical systems, and/or nano-optoelectronic-mechanical systems fabrication techniques.

The electric field intensity of the on-resonance frequency (wavelength) can get very high (magnified) in high Q-factor optical resonator cavities. This magnified electric field intensity in turn can result in very high (increased) absorption of the on-resonance wavelength when an absorber (absorbing at the on resonance wavelength) is placed inside the resonator cavity.

Pumping light can be of any wavelength(s) suitable for the intended functioning of the device or system. Exemplary wavelengths that can be contained in pumping light include wavelengths in the infrared (e.g., near), visible, and ultraviolet (near and deep) classes of the electromagnetic spectrum. Correspondingly, each light source can be a device that generates electromagnetic radiation at one or more wavelengths that fall within these classes and that are commensurate with the design of the optical resonator(s). Examples of such devices include, but are not limited to, light-emitting diodes, lasers (e.g., semiconductor, solid state, gas, photonic crystal, exiplex, chemical, etc.), lamps, etc. Some specific examples of devices that can be used for each light source are provided the foregoing examples. However, those skilled in the art will readily understand that the exemplary embodiments are provided for illustrative purposes and, therefore, should not be considered limiting relative to the scope of the inventions as defined in the appended claims.

In some embodiments, the light source is an LD or LED emitting so that pumping light is at a single primary wavelength. Each LD or LED can be, for example, a wide-area source that has an emitting area that substantially corresponds to the area of resonator structure. If light source emits a relatively narrow beam (not shown) of light relative to the area of resonator structure, it can utilize a suitable beam expander (not shown), as known in the art. In other embodiments, light source may be composed of one or more individual light sources (not shown) for each downconverter. In such embodiments, such light sources can all emit light at the same primary wavelength, or they could emit light at different wavelengths, with each wavelength selected based on the design of the corresponding downconverter.

Similarly, working light can be of any wavelength(s) that optical resonator(s) is/are capable of outputting based on pumping light. Examples of wavelengths that can be contained in working light include wavelengths in the infrared (e.g., near), visible, and ultraviolet (near and deep) classes of the electromagnetic spectrum. As those skilled in the art will appreciate, the design of OSPEE resonator(s) can be tuned to output one or more desired wavelengths and/or to output light of a particular polarization. As will be seen below, such tuning can be achieved, for example, by properly selecting a suitable material for each phosphor used, properly locating and arranging each phosphor structure (e.g., quantum-confining structure), and properly locating and arranging optical resonator cavities, among other things. Specific examples are provided in PCT Patent Application PCT/US12/30540, filed on Mar. 26, 2012, and titled “RESONATOR-ENHANCED OPTOELECTRONIC DEVICES AND METHODS OF MAKING SAME.” to illustrate design methodologies that can be used to create each optical resonator and to illustrate particular useful applications of such optical resonators. The revealed architecture could be used to create novel optically pumped VCSELs, VECSELs, OPS-VECSELs, VCSOAs, OPSL, SDL, etc. It could also be used to enhance the efficiency of phenomena such as superradiance, superfluorescence, coherence brightening, amplified spontaneous emission, optical gain, etc.

It is noted that the placement of a phosphor layer in an optical resonator is known, and in that context the phosphor layer is called an “optical gain media” or the overall arrangement is called an “optical amplifier arrangement,” among other things. However, to the best of the inventor's knowledge, photoluminescent phosphors have not commonly been used in such an arrangement for a variety of reasons. For example, if an LED light source is used to pump a conventional phosphor-containing optical arrangement, the single-cavity resonator will only support a very narrow range of wavelengths that will be on resonance for the LEDs input light source. Therefore, a significant spectrum of the LED input simply does not get into the single-cavity resonator to get absorbed in the phosphor layer, which would lead to high efficiency loss outright. This situation is further exacerbated as the Q-factor of the resonator gets higher. A higher Q-factor leads to reduction/narrowing of the bandwidth (band pass) of the resonator. In a similar fashion, if an LD is used to “pump” a conventional single-cavity phosphor-containing resonator, the LD would need to be wavelength stabilized (additional expense with heat sinks and sensors). Otherwise small shifts in the LD wavelength would result in significant shifts in the absorption in the phosphor layer, resulting in widely fluctuating output wavelength and amplitude.

An OSPEE device according to embodiments of the present invention can be used to create optically pumped edge-emitting devices that function the same as or similar to LEDs, SLEDs, LDs, OPSL, SDSs, SOA (semiconductor Optical Amplifiers) etc., and/or to enhance the efficiency of phenomena such as superradiance, superfluorescence, coherence brightening, amplified spontaneous emission (ASE), and/or optical gain, among others. Such devices can be tuned to produce light in UV, visible, NIR, MWIR, FIR, etc., regions of the electromagnetic spectrum, can have optical power output characteristics ranging from low to very high, and can be implemented using any suitable phosphor material. If desired, such OSPEE devices may also be tailored to create optically pumped edge-emitting devices that operate the same as or similar to polariton-based LEDs, SLEDs, and LDs, among others.

Depending on application, power requirements, size constraints, etc., it may be desirable to vary the physical/geometrical forms of phosphor structure(s) and/or waveguide structure(s). Such structures may be provided in physical/geometrical forms such as (but not limited to): slab, planar, strip, rectangular, rib, segmented, photonic crystal, and/or photonic integrated optical circuit (PIOC). Circular, hexagonal, and other non-rectangular cross-sectional waveguides can also be implemented and are particularly useful for use with optical fibers and the like. Waveguides can be formed of any suitable material and can be inorganic, organic, or hybrid (combination organic/inorganic) in composition.

If a II-VI material is used as a phosphor in an OSPEE resonator of the present invention, the II-VI coating layer structure may be zinc blende or wurtzite. As an example, CdS may be used for barrier layers, and CdSe may be used for quantum-well layers within the phosphor structure. Each barrier layer may be composed of a semiconductor or insulator material. Other III-V materials that can be used for quantum confining layers include, for example, GaN, AlGaN, InGaN, BN, and any other suitable material.

Currently the industry is lacking suitable green LEDs and LDs, whereas blue and violet LEDs and LDs are widely available. An OSPEE device made in accordance with the present invention may be used to downconvert a pumping blue/violet LED or LD to generate green, red, and/or blue LEDs and LDs. One of the biggest contemporary challenges in realizing an InGaN-based green LED is the migration of the indium from the quantum wells under the high temperatures used in processing the device. Clearly the photoluminescent-phosphor-based downconversion solution of the present embodiment does not need the p- and n-type layers bounding the InGaN, as is usual in a conventional electroluminescent device. As a result, one can simply implement InGaN quantum wells that are already realizable using established infrastructure and processing in optical resonator designs disclosed herein to realize long-lasting, high-quality green LEDs and LDs and LED- and LD-like devices.

The band gaps of the quantum wells material(s) and the barrier layer material(s) may be chosen so that the input/pump wavelength are absorbed only in the quantum well layers or also in the barrier layers. The quantum wells (if more than one) may be all of the same thickness or different thicknesses and/or compositions. Similarly the barrier layers may be all of the same thickness or different thicknesses and/or compositions. Each quantum well may or may not be located at an anti-node of the standing wave in the resonator cavity.

As mentioned above, various embodiments of the optical resonator architectures disclosed herein utilize quantum-confining structures as photoluminescent absorbing structures, including quantum dots. When quantum dots are used in those embodiments, it is generally contemplated that they are used in their standard form, i.e., without any surface coatings. However, in other embodiments the present inventor proposes use of specially processed quantum dots having integrated reflectors applied to their surfaces.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. An optical system, comprising:
an optical device designed and configured to output working light of a first spectral composition in response to receiving pumping light of a second spectral composition different from the first spectral composition, said optical device including:
a plurality of layers having a stacking direction, first and second faces spaced along said stacking direction, and an edge extending between said first and second faces, wherein said plurality of layers are designed, arranged, and configured to define a resonator cavity designed and configured to resonate at a resonant frequency tuned to the second spectral composition;
a first photoluminescent layer located within said resonator cavity, said first photoluminescent layer designed and configured to create luminescence of the first spectral composition in response to stimulation by the pumping light when the pumping light is received through at least one of said first and second faces; and
a waveguide designed and configured as a function of said first spectral composition so as to guide the luminescence toward said edge so as to output the working light through said edge.

2. An optical system according to claim 1, wherein said waveguide is defined amongst said plurality of layers.

3. An optical system according to claim 2, wherein said waveguide is provided by a separate confinement heterostructure.

4. An optical system according to claim 2, wherein a first set of layers of said plurality of layers defines a first distributed Bragg reflector for said resonator cavity and a second set of layers of said plurality of layers defines a second distributed Bragg reflector for said resonator cavity, wherein said waveguide is defined amongst said first and second sets of layers.

5. An optical system according to claim 2, wherein a first set of layers of said plurality of layers defines a first non-distributed-Bragg reflector for said resonator cavity and a second set of layers of said plurality of layers defines a second non-distributed-Bragg reflector for said resonator cavity, wherein said waveguide is defined amongst said first and second sets of layers.

6. An optical system according to claim 2, wherein said waveguide comprises at least one absentee layer located amongst said plurality of layers.

7. An optical system according to claim 6, wherein said plurality of layers defines first and second distributed Bragg reflectors defining said resonator cavity, said waveguide comprising at least one absentee layer in each of said first and second distributed Bragg reflector.

8. An optical system according to claim 1, wherein said resonator cavity is located within said waveguide.

9. An optical system according to claim 1, wherein said resonator cavity has a midpoint axis perpendicular to said stacking axis, and said waveguide is concentric with said resonator cavity about said midpoint axis.

10. An optical system according to claim 1, wherein said resonator cavity has a midpoint axis perpendicular to said stacking axis, and said waveguide is eccentric with said resonator cavity about said midpoint axis.

11. An optical system according to claim 1, wherein said waveguide is located outside said resonator cavity.

12. An optical system according to claim 1, further comprising a light source located relative to said optical device so as to provide said pumping light to said first photoluminescent layer through at least one of said first and second faces.

13. An optical system according to claim 12, wherein said light source is formed integrally with said optical device.

14. An optical system according to claim 1, further comprising:
a first light source located relative to said optical device so as to provide a first portion of said pumping light to said first photoluminescent layer through said first face; and
a second light source located relative to said optical device so as to provide a second portion of said pumping light to said first photoluminescent layer through said second face.

15. An optical system according to claim 14, wherein each of said first and second light sources are formed integrally with said optical device.

16. An optical system according to claim 1, wherein said first photoluminescent layer has uniform thickness.

17. An optical system according to claim 1, wherein said first photoluminescent layer has varying thickness.

18. An optical system according to claim 1, wherein said plurality of layers further:
are designed, arranged, and configured to define a second resonator cavity designed and configured to resonate at a resonant frequency tuned to at least one of the second or a third spectral compositions;
include a second photoluminescent layer within said second resonator cavity, said photoluminescent layer designed and configured to create luminescence of said third spectral composition in response to stimulation by the pumping light when the pumping light is received through at least one of said first and second faces; and
are designed, arranged, and configured to define a second waveguide to guide the luminescence toward said edge so as to output working light of said third spectral composition through said edge.

19. An optical system according to claim 1, wherein said edge is a first edge and said plurality of layers has a second edge, said optical device further comprising a first feedback mirror extending along said second edge.

20. An optical system according to claim 19, wherein said second edge is located opposite said first edge.

21. An optical system according to claim 19, wherein said second edge is substantially perpendicular to said first edge.

22. An optical system according to claim 21, wherein said plurality of layers has a third edge spaced from said second edge, said optical device further comprising a second feedback mirror extending along said third edge.

23. An optical system according to claim 21, wherein said plurality of layers has a fourth edge spaced from said first edge, said optical device further comprising a third feedback mirror extending along said fourth edge.

24. An optical system according to claim 1, wherein the working light is composed substantially of a single wavelength.

25. An optical system according to claim 1, wherein the working light is composed of multiple wavelengths.

26. An optical system according to claim 1, wherein said optical device is an optically pumped laser.

27. An optical system according to claim 1, wherein said optical device is an optically pumped superluminescent light emitting device.

28. An optical system according to claim 1, wherein said optical device is a semiconductor optical amplifier.

29. A method of making an optical system that includes an optical device designed and configured to output working light from an edge of the optical device in response to being pumped with pumping light through a face of the optical device, the method comprising:
arranging and configuring a plurality of layers within the optical device so as to define at least one resonator cavity designed and configured to resonate at a spectral frequency of the pumping light;
providing a first photoluminescent layer within said at least one resonator cavity, wherein the first photoluminescent layer is designed and configured to provide luminescence in response to the pumping light; and
providing a waveguide to guide the luminescence toward the edge of the optical device so as to output the working light through the edge of the optical device.

30. A method according to claim 29, wherein said providing a waveguide includes arranging and configured ones of the plurality of layers so as to function as components of the waveguide.

31. A method according to claim 30, wherein said arranging and configuring a plurality of layers includes arranging and configured a first set of the plurality of layers to define a first distributed Bragg reflector and arranging an configuring a second set of the plurality of layers to define a second distributed Bragg reflector.

32. A method according to claim 30, wherein said arranging and configuring a plurality of layers includes arranging and configured a first set of the plurality of layers to define a first non-distributed-Bragg reflector and arranging an configuring a second set of the plurality of layers to define a second non-distributed-Bragg reflector.

33. A method according to claim 30, wherein said providing a waveguide include providing an absentee layer to the plurality of layers.

34. A method according to claim 29, wherein said providing a waveguide includes providing the optical device with a separate confinement heterostructure.

35. A method according to claim 29, wherein said providing a waveguide includes providing the waveguide adjacent to the at least one optical resonator cavity.

36. A method according to claim 29, wherein the at least one resonator cavity has a corresponding midpoint axis and said providing a waveguide includes providing the waveguide so that the waveguide is concentric with the at least one resonator cavity about the midpoint axis.

37. A method according to claim 29, wherein the at least one resonator cavity has a corresponding midpoint axis and said providing a waveguide includes providing the waveguide so that the waveguide is eccentric with the at least one resonator cavity about the midpoint axis.

38. A method according to claim 29, wherein said providing a first photoluminescent layer comprises providing the first photoluminescent layer with a uniform thickness.

39. A method according to claim 29, wherein said providing a first photoluminescent layer comprises providing the first photoluminescent layer with a varying thickness.

40. A method according to claim 29, further comprising providing a light source adjacent to the face and configuring the light source to provide the pumping light to the at least one resonator cavity through the face.

41. A method according to claim 40, wherein said providing a light source includes providing the light source so that it is integral with the plurality of layers.

42. A method according to claim 40, wherein the optical device has a second face and the method further comprises providing a second light source adjacent to the second face and configuring the second light source to provide the pumping light to that at least one resonator cavity through the second face.

43. A method according to claim 42, wherein said providing a second light source includes providing the second light source so that it is integral with the plurality of layers.

44. A method according to claim 29, further comprising:
arranging and configuring a plurality of layers within the optical device so as to define a second resonator cavity designed and configured to resonate at a spectral frequency of at least one of the pumping light and the working light;
providing a second photoluminescent layer within said second resonator cavity, wherein the photoluminescent layer is designed and configured to provide luminescence of a third spectral frequency in response to the pumping light; and
providing a second waveguide to guide the luminescence of said third spectral frequency toward the edge of the optical device so as to output the working light of said third spectral frequency through the edge of the optical device.

45. A method according to claim 29, wherein the edge is a first edge and the method further comprises providing a first feedback mirror to a second edge of the optical device.

46. A method according to claim 45, further comprising locating the second edge opposite the first edge.

47. A method according to claim 45, further comprising locating the second edge so as to be perpendicular to the first edge.

48. A method according to claim 47, further comprising:
providing a third edge spaced from the second edge; and
providing a second feedback minor to said third edge.

49. A method according to claim 47, further comprising:
providing a fourth edge spaced from the first edge; and
providing a third feedback minor to said fourth edge.

50. A method according to claim 29, further comprising tuning the optical device so that the working light is composed of substantially only one wavelength when subjected to the pumping light.

51. A method according to claim 29, further comprising tuning the optical device so that the working light is composed of multiple selected wavelengths.

52. A method according to claim 29, further comprising configuring the optical device so that it functions as a laser in response to the pumping light.

53. A method according to claim 29, further comprising configuring the optical device so that it functions as a superluminescent light emitting device in response to the pumping light.

54. A method according to claim 29, further comprising configuring the optical device so that it functions as a semiconductor optical amplifier in response to the pumping light.
